(19) United States
(12) Patent Application Publication
(10) Pub. No.: US 2025/0126806 A1
(43) Pub. Date: Apr. 17, 2025

(54) DOMAIN WALL MOTION ELEMENT AND MAGNETIC ARRAY

(71) Applicant: TDK CORPORATION, Tokyo (JP)

(72) Inventors: Toshiki GUSHI, Tokyo (JP); Shogo Yamada, Tokyo (JP); Tatsuo Shibata, Tokyo (JP); Tomoyuki Sasaki, Tokyo (JP)

(73) Assignee: TDK CORPORATION, Tokyo (JP)

(21) Appl. No.: 18/999,700

(22) Filed: Dec. 23, 2024

Related U.S. Application Data
(63) Continuation-in-part of application No. PCT/JP2022/026190, filed on Jun. 30, 2022.

(51) Int. Cl. H10B 61/00

(52) U.S. Cl. CPC H10B 61/20

(57) ABSTRACT

This domain wall motion element includes a first magnetoresistance effect element and a first transistor. A first domain wall displacement layer of the first magnetoresistance effect element is electrically connected to a first active region of the first transistor. The length of the first magnetoresistance effect element in a first direction is longer than the length thereof in a second direction. The length of a first gate in the first direction is longer than the length thereof in the second direction. The length of the first magnetoresistance effect element in the first direction is longer than the length of the first gate in the first direction. A first gate length direction connecting the first active region and a second active region intersects with the first direction.

### TECHNICAL FIELD

The present disclosure relates to a domain wall motion element and a magnetic array.

### BACKGROUND ART

There is known a magnetoresistance effect element that uses a change in resistance (magnetoresistance change) based on a change in the relative angle between the magnetizations of two ferromagnetic layers. For example, Patent Document 1 discloses a domain wall motion type magnetoresistance effect element. In the domain wall motion type magnetoresistance effect element, the resistance value in the lamination direction changes depending on the position of the domain wall, and data can be recorded in a multi-value or analog form.

The domain wall motion type magnetoresistance effect element can be used in a neuromorphic device that mimics the functions of the brain, as described in, for example, Patent Document 2.

### CITATION LIST

### Patent Document

Patent Document 1: Japanese Patent No. 5441005
Patent Document 2: Japanese Unexamined Patent Application, First Publication No. 2020-053660

### SUMMARY OF INVENTION

### Technical Problem

The magnetoresistance effect element is often used as a magnetic array that integrates a plurality of elements. High integration of the magnetic array is required to process a large amount of information in a small area. The domain wall motion type magnetoresistance effect element can express more states as the domain wall has a wider movement range. In order to widen the movement range of the domain wall, the shape of the magnetoresistance effect element becomes longer in one direction. Further, in the domain wall motion type magnetoresistance effect element, the write current is larger than the read current. In order to ensure a sufficient amount of write current, it is necessary to use transistors with a large rated current, which increases the gate width of the transistors. That is, there are limitations on the shape and size of both the magnetoresistance effect elements and the transistors constituting the magnetic array.

The present disclosure has been made in consideration of the above problems, and has an object to provide a domain wall motion element and a magnetic array that can be highly integrated.

### Solution to Problem

(1) A domain wall motion element according to a first aspect includes a first magnetoresistance effect element and a first transistor. The first magnetoresistance effect element includes a first domain wall displacement layer, a first ferromagnetic layer, and a first non-magnetic layer sandwiched between the first domain wall displacement layer and the first ferromagnetic layer. The first transistor includes a first active region, a second active region, and a first gate controlling a current between the first active region and the second active region. The first domain wall displacement layer is electrically connected to the first active region. The length of the first magnetoresistance effect element in the first direction is longer than the length thereof in the second direction orthogonal to the first direction. The length of the first gate in the first direction is longer than the length thereof in the second direction. The length of the first magnetoresistance effect element in the first direction is longer than the length of the first gate in the first direction. A first gate length direction of connecting the first active region and the second active region intersects with the first direction.

(2) The domain wall motion element according to the above aspect may further include a second magnetoresistance effect element. The second magnetoresistance effect element includes a second domain wall displacement layer, a second ferromagnetic layer, and a second non-magnetic layer sandwiched between the second domain wall displacement layer and the second ferromagnetic layer. The first transistor further includes a third active region and a second gate controlling a current between the second active region and the third active region. The second domain wall displacement layer is electrically connected to the third active region.

(3) The domain wall motion element according to the above aspect may further include a second transistor. The second transistor includes a fourth active region, a fifth active region, a sixth active region, a third gate controlling a current between the fourth active region and the fifth active region, and a fourth gate controlling a current between the fifth active region and the sixth active region. The fourth active region is electrically connected to the first domain wall displacement layer. The sixth active region is electrically connected to the second domain wall displacement layer.

(4) The domain wall motion element according to the above aspect may further include a second transistor and a third magnetoresistance effect element. The second transistor includes a fourth active region, a fifth active region, a sixth active region, a third gate controlling a current between the fourth active region and the fifth active region, and a fourth gate controlling a current between the fifth active region and the sixth active region. The third magnetoresistance effect element includes a third domain wall displacement layer, a third ferromagnetic layer, and a third non-magnetic layer sandwiched between the third domain wall displacement layer and the third ferromagnetic layer. The fourth active region is electrically connected to the second domain wall displacement layer. The sixth active region is electrically connected to the third domain wall displacement layer.

(5) The domain wall motion element according to the above aspect may further include a substrate. The first ferromagnetic layer may be closer to the substrate than the first domain wall displacement layer. The first conductive layer electrically connected to the first active region may be connected to an upper surface of the first domain wall displacement layer.

(6) In the domain wall motion element according to the above aspect, at least a part of the first active region may not overlap with the first domain wall displacement layer when viewed from a lamination direction.

(7) The domain wall motion element according to the above aspect may further include a second transistor. The second transistor includes a fourth active region, a fifth active region, and a third gate controlling a current between the fourth active region and the fifth active region. A length of the third gate in the first direction is longer than a length thereof in the second direction. A length of the first magnetoresistance effect element in the first direction is shorter than a sum of the lengths of the first gate and the third gate in the first direction.

(8) In the domain wall motion element according to the above aspect, a first channel between the first active region and the second active region may contain an oxide containing any one or more elements selected from the group consisting of In, Ga, Zn, and Al.

(9) The domain wall motion element according to the above aspect may further include a second magnetoresistance effect element. The second magnetoresistance effect element includes a second domain wall displacement layer, a second ferromagnetic layer, and a second non-magnetic layer sandwiched between the second domain wall displacement layer and the second ferromagnetic layer. The first magnetoresistance effect element and the second magnetoresistance effect element may be located at different positions in the lamination direction.

(10) The domain wall motion element according to the above aspect may further include a second magnetoresistance effect element. The second magnetoresistance effect element includes a second domain wall displacement layer, a second ferromagnetic layer, and a second non-magnetic layer sandwiched between the second domain wall displacement layer and the second ferromagnetic layer. At least one transistor connected to the first magnetoresistance effect element or the second magnetoresistance effect element may have a channel formed in a lamination direction connecting two active regions.

(11) A magnetic array according to a second aspect includes the domain wall motion element according to the above aspect.

### Advantageous Effects of Invention

The domain wall motion element and the magnetic array according to the above aspects are excellent in integration properties.

### BRIEF DESCRIPTION OF DRAWINGS

FIG. 1 A block diagram of a magnetic array according to a first embodiment.

FIG. 2 A circuit diagram of an integration region of the magnetic array according to the first embodiment.

FIG. 3 A plan view of a domain wall motion element according to the first embodiment.

FIG. 4 A cross-sectional view of the domain wall motion element according to the first embodiment.

FIG. 5 A cross-sectional view of a magnetoresistance effect element according to the first embodiment.

FIG. 6 A cross-sectional view of the domain wall motion element according to the first embodiment.

FIG. 7 A cross-sectional view of the domain wall motion element according to the first embodiment.

FIG. 8 A plan view of a domain wall motion element according to a second embodiment.

FIG. 9 A plan view of a domain wall motion element according to a third embodiment.

FIG. 10 A cross-sectional view of the domain wall motion element of the third embodiment.

FIG. 11 A cross-sectional view of the domain wall motion element according to the third embodiment.

FIG. 12 A plan view of a domain wall motion element according to a fourth embodiment.

FIG. 13 A plan view of a domain wall motion element according to a fifth embodiment.

FIG. 14 A cross-sectional view of the domain wall motion element according to the fifth embodiment.

FIG. 15 A cross-sectional view of a domain wall motion element according to a sixth embodiment.

FIG. 16 A cross-sectional view of a domain wall motion element according to a seventh embodiment.

FIG. 17 A plan view showing a wiring connected to a transistor of the domain wall motion element according to the third embodiment.

FIG. 18 A plan view showing a wiring connected to a transistor of the domain wall motion element according to the fourth embodiment.

### DESCRIPTION OF EMBODIMENTS

Hereinafter, this embodiment will be described in detail with reference to the drawings. The drawings used in the following description may show characteristic parts in an enlarged scale for the sake of convenience in order to make the characteristics easier to understand, and the dimensional ratios of each component may differ from the actual ones. The materials, dimensions, and the like exemplified in the following description are merely examples, and the present disclosure is not limited to them. They can be modified as appropriate within the scope of the effects of the present disclosure.

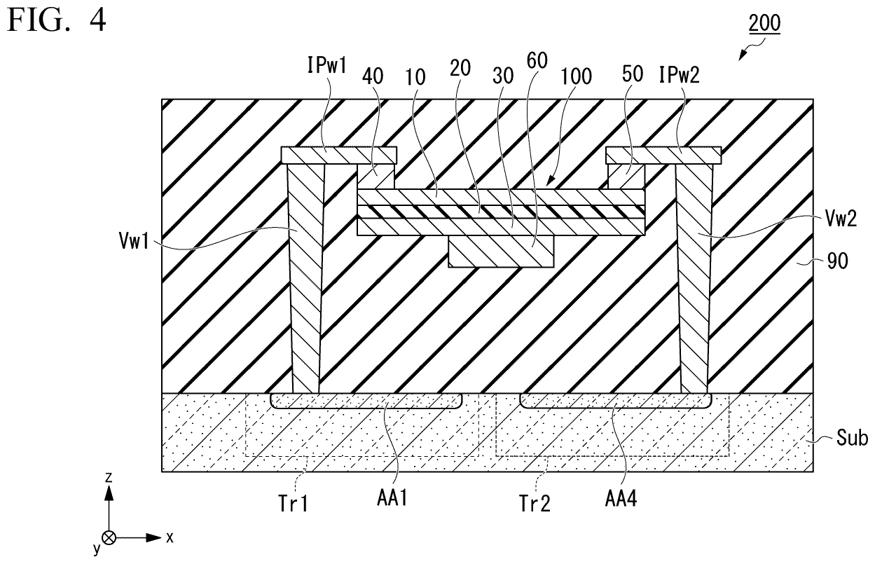

First, directions will be defined. The x and y directions are substantially parallel to one surface of a substrate Sub (see FIG. 4) described later. The x direction is the longitudinal direction of a domain wall displacement layer 10 described later, and may be referred to as the first direction. The y direction is the direction orthogonal to the x direction. The y direction may be referred to as the second direction. The z direction is the direction from the substrate Sub to a magnetoresistance effect element 100, which will be described later. The z direction may be referred to as the lamination direction. In this specification, the +z direction may be expressed as “up” and the −z direction as “down”, but these expressions are for convenience only and do not define the direction of gravity. In addition, in this specification, “connection” is not limited to a direct connection, but also includes a connection via another object.

### First Embodiment

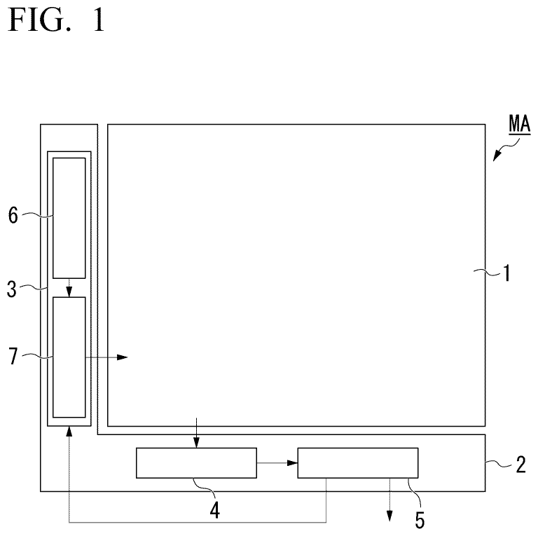

FIG. 1 is a block diagram of a magnetic array MA according to a first embodiment. The magnetic array MA includes an integration region 1 and a peripheral region 2. The magnetic array MA can be used, for example, in a magnetic memory, a multiply-and-accumulate unit, a neuromorphic device, a spin memristor, or a magneto-optical element.

The integration region 1 is a region in which a plurality of domain wall motion elements are integrated. The domain wall motion element includes a magnetoresistance effect element and a transistor connected to the magnetoresistance effect element. When the magnetic array MA is used as a memory, data is stored in the integration region 1. When the magnetic array MA is used as a neuromorphic device, learning takes place in the integration region 1.

The peripheral region 2 is a region in which a control element for controlling the operation of the domain wall motion element in the integration region 1 is mounted. The peripheral region 2 includes, for example, a pulse application device 3, a resistance detection device 4, and an output unit 5.

The pulse application device 3 is configured to apply a pulse to at least one of the plurality of domain wall motion elements in the integration region 1. The pulse application device 3 includes, for example, a control unit 6 and a power source 7.

The control unit 6 includes, for example, a processor and a memory. The processor is, for example, a CPU (Central Processing Unit). The processor is operated based on an operation program stored in the memory. The control unit 6 controls, for example, the address of the domain wall motion element to which the pulse is applied, the magnitude (voltage, pulse length) of the pulse applied to a predetermined domain wall motion element, etc. The control unit 6 may also include a clock, a counter, a random number generator, etc. The clock is an index of the timing of applying a pulse, and the counter counts the number of times the pulse is applied. The power source 7 applies a pulse toward the domain wall motion element according to an instruction from the control unit 6.

The resistance detection device 4 is configured to detect the resistance value of the magnetoresistance effect element in the integration region 1. The resistance detection device 4 may detect the resistance of each of the magnetoresistance effect elements in the integration region 1 or may detect the total resistance of the magnetoresistance effect elements belonging to the same column, for example. The resistance detection device 4 may include, for example, a comparator for comparing the magnitude of the detected resistance value. The comparator may, for example, compare the detected resistance values with each other, or may compare the detected resistance value with a preset reference resistance value.

The output unit 5 is connected to the resistance detection device 4. The output unit 5 includes, for example, a processor, an output capacitor, an amplifier, a converter, etc. When the magnetic array MA is used as a neuromorphic device, the output unit 5 may perform a calculation to substitute the detection result of the resistance detection device 4 into an activation function. The calculation is performed by, for example, the processor. The output unit 5 outputs the calculation result to the outside. When the magnetic array MA is used as a neuromorphic device, for example, the calculation result may be output as an input signal for another magnetic array, or may be output to the outside as a discrimination rate. Further, the output unit 5 may send the calculation result to the pulse application device 3 as feedback.

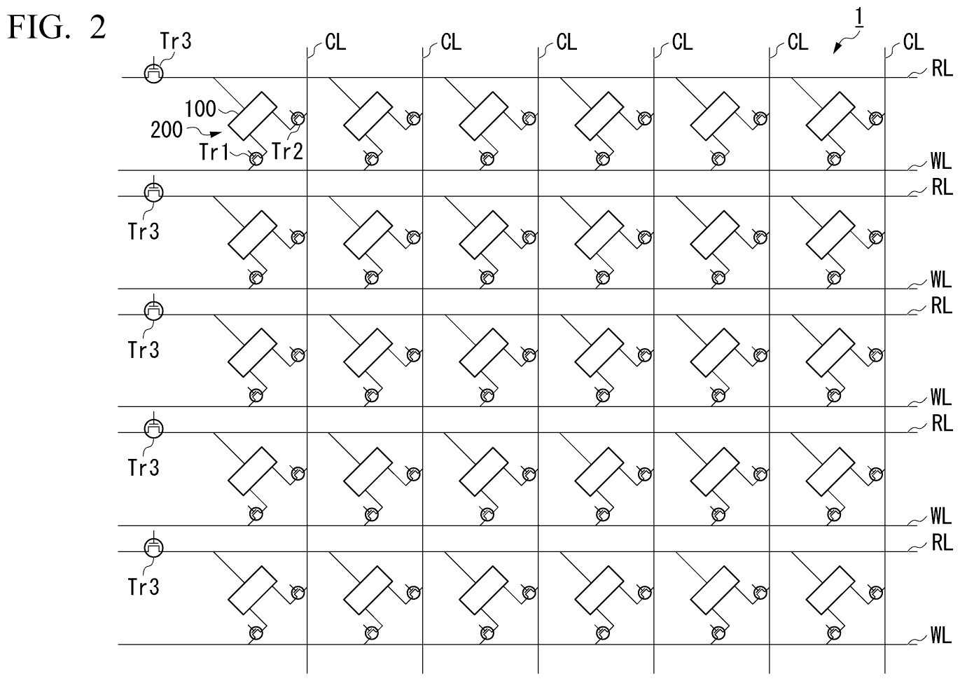

FIG. 2 is a circuit diagram of the integration region 1 according to the first embodiment. The integration region 1 includes a plurality of domain wall motion elements 200, a plurality of first wirings WL, a plurality of second wirings CL, and a plurality of third wirings RL. Each of the domain wall motion elements 200 includes the magnetoresistance effect element 100, a first transistor Tr1, and a second transistor Tr2. A third transistor Tr3 belongs to the pulse application device 3 in the peripheral region 2, for example.

The plurality of domain wall motion elements 200 are arranged, for example, in a matrix. The plurality of domain wall motion elements 200 are not limited to those arranged in a matrix in actuality, but may be arranged in a matrix in a circuit diagram.

Each of the first wirings WL is, for example, a write wiring. Each of the first wirings WL electrically connects the pulse application device 3 to one or more magnetoresistance effect elements 100. Each of the second wirings CL is, for example, a common wiring that can be used both when writing and reading data. Each of the second wirings CL is connected to, for example, the resistance detection device 4. The second wiring CL may be provided for each of the plurality of magnetoresistance effect elements 100, or may be provided across the plurality of magnetoresistance effect elements 100. Each of the third wirings RL is, for example, a read wiring. Each of the third wirings RL electrically connects the pulse application device 3 to one or more magnetoresistance effect elements 100.

The first transistor Tr1, the second transistor Tr2, and the third transistor Tr3 are elements that control the flow of current. The first transistor Tr1 is a field effect transistor. The second transistor Tr2 and the third transistor Tr3 may be field effect transistors or other elements that control the flow of current. Other elements that control the flow of current include, for example, elements that use a phase change of a crystal layer such as an Ovonic Threshold Switch (OTS), elements that use a change in band structure such as a Metal-Insulator Transition (MIT) switch, elements that use a breakdown voltage such as a Zener diode and an avalanche diode, and elements whose conductivity changes with a change in atomic position.

The first transistor Tr1 and the second transistor Tr2 are connected to, for example, each of the magnetoresistance effect elements 100. The first transistor Tr1 is connected, for example, between the magnetoresistance effect element 100 and the first wiring WL. The second transistor Tr2 is connected, for example, between the magnetoresistance effect element 100 and the second wiring CL. The third transistor Tr3 is connected, for example, across the plurality of magnetoresistance effect elements 100. The third transistor Tr3 is connected to, for example, the third wiring RL. Each of the first transistor Tr1, the second transistor Tr2, the third transistor Tr3 is connected to, for example, a gate wiring (not shown) that controls the operation of each transistor.

The positional relationship of the second transistor Tr2 and the third transistor Tr3 is not limited to the case shown in FIG. 2. For example, the second transistor Tr2 may be connected across the plurality of magnetoresistance effect elements 100 and connected to one end of the second wiring CL. Further, for example, the third transistor Tr3 may be connected to each of the magnetoresistance effect elements 100 one by one.

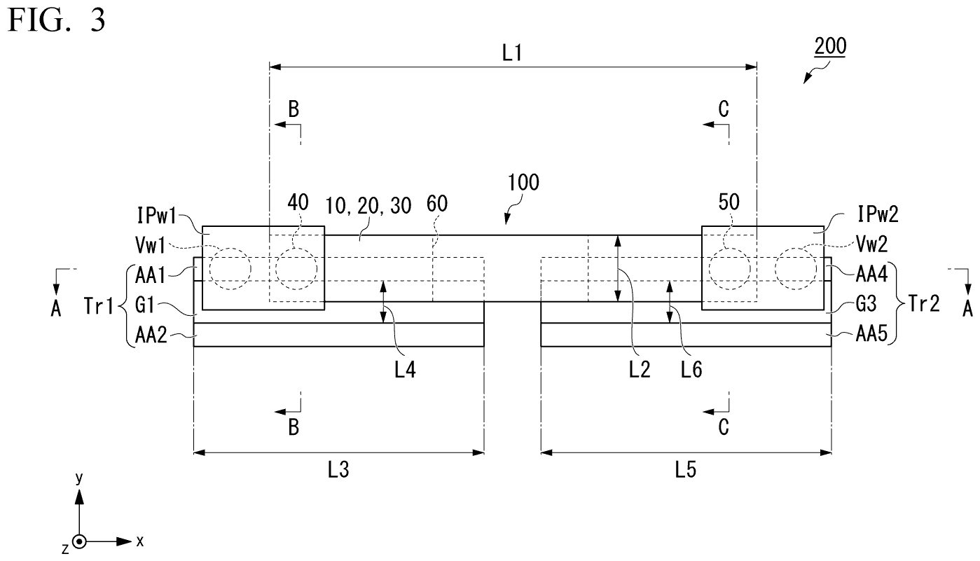

FIG. 3 is a plan view of a domain wall motion element 200 according to the first embodiment. FIG. 4 is a cross-sectional view of the domain wall motion element 200 according to the first embodiment. FIG. 4 is a cross-sectional view taken along line A-A of FIG. 3.

The domain wall motion element 200 includes the magnetoresistance effect element 100, the first transistor Tr1, and the second transistor Tr2.

The magnetoresistance effect element 100 and the first transistor Tr1 are electrically connected via a vertical wiring Vw1 and an in-plane wiring IPw1. The magnetoresistance effect element 100 and the second transistor Tr2 are electrically connected via a vertical wiring Vw2 and an in-plane wiring IPw2. The vertical wiring Vw1 and the vertical wiring Vw2 are wirings extending in the z direction. The in-plane wiring IPw1 and the in-plane wiring IPw2 are wirings extending in any direction within the xy plane. The vertical wiring Vw1, the vertical wiring Vw2, the in-plane wiring IPw1, and the in-plane wiring IPw2 are conductors.

The periphery of the magnetoresistance effect element 100 is covered with an insulating layer 90. The insulating layer 90 is an insulating layer that provides insulation between wirings in a multi-layer wiring structure and between elements. The insulating layer 90 is, for example, silicon oxide (SiOx), silicon nitride (SiNx), silicon carbide (SiC), chromium nitride, silicon carbonitride (SiCN), silicon oxynitride (SiON), aluminum oxide (Al₂O₃), zirconium oxide (ZrOx), or the like.

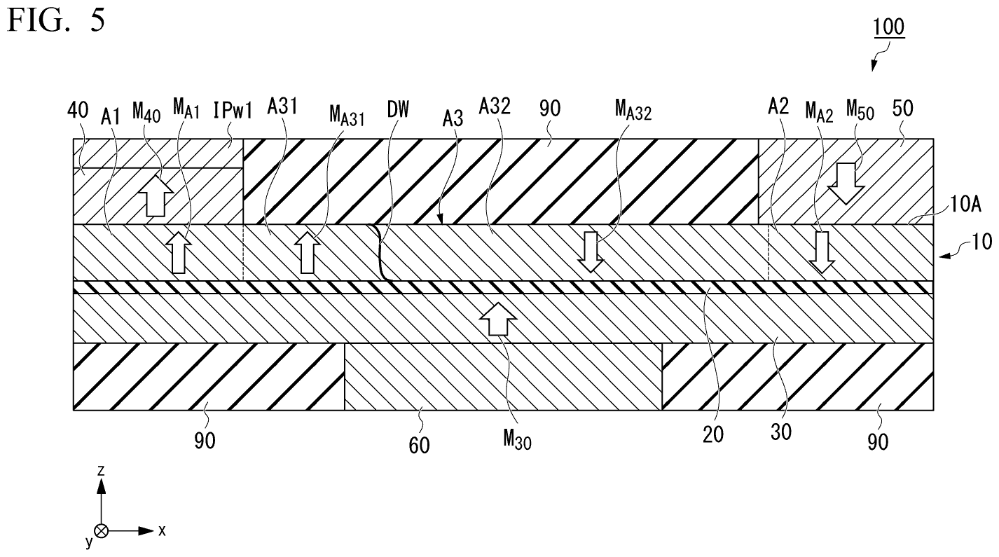

FIG. 5 is a cross-sectional view of the magnetoresistance effect element 100 according to the first embodiment. FIG. 5 is a cross-sectional view taken along line A-A of FIG. 3. The arrows shown in the figure are examples of the orientation direction of magnetization of a ferromagnetic material.

The magnetoresistance effect element 100 includes, for example, a domain wall displacement layer 10, a non-magnetic layer 20, a ferromagnetic layer 30, a first conductive layer 40, a second conductive layer 50, and a third conductive layer 60.

When viewed from the z direction, a length L1 in the x direction of the magnetoresistance effect element 100 is longer than a length L2 in the y direction (see FIG. 3). Hereinafter, the length of the magnetoresistance effect element is defined as the length of the portion where the first ferromagnetic layer, the non-magnetic layer, and the ferromagnetic layer overlap when viewed from the z direction.

The domain wall displacement layer 10 has a length in the x direction longer than the length in the y direction. The domain wall displacement layer 10 has a plurality of magnetic domains therein and a magnetic domain wall DW at the boundary between a plurality of the magnetic domains. The domain wall displacement layer 10 is, for example, a layer that can magnetically record information by changing a magnetic state. The domain wall displacement layer 10 is also referred to as an analog layer or a magnetic recording layer.

The domain wall displacement layer 10 has a first region A1, a second region A2, and a third region A3. The first region A1 is a region that overlaps with the first conductive layer 40 when viewed from the z direction. The second region A2 is a region that overlaps with the second conductive layer 50 when viewed from the z direction. The third region A3 is a region other than the first region A1 and the second region A2 of the domain wall displacement layer 10. The third region A3 is, for example, sandwiched between the first region A1 and the second region A2 in the x direction.

The magnetization M_{A1} of the first region A1 is fixed by the first conductive layer 40. The magnetization M_{A2} of the second region A2 is fixed by the second conductive layer 50. The state in which the magnetization is fixed means that the magnetization does not reverse during normal operation of the magnetoresistance effect element 100 (when no external force exceeding the expected value is applied). The magnetization M_{A1} of the first region A1 and the magnetization M_{A2} of the second region A2 are oriented in, for example, opposite directions.

The third region A3 is a region where the magnetization direction changes and the domain wall DW can move. The third region A3 is referred to as a region in which the domain wall can move. The third region A3 has a first magnetic domain A31 and a second magnetic domain A32. The magnetizations of the first magnetic domain A31 and the second magnetic domain A32 are oriented in opposite directions. The boundary between the first magnetic domain A31 and the second magnetic domain A32 is the domain wall DW. The magnetization M_{A31} of the first magnetic domain A31 is oriented in the same direction as the magnetization M_{A1} of the first region A1, for example. The magnetization M_{A32} of the second magnetic domain A32 is oriented in the same direction as the magnetization M_{A2} of the adjacent second region A2, for example. The domain wall DW moves in the third region A3 in principle and does not invade the first region A1 or the second region A2.

When the volume ratio between the first magnetic domain A31 and the second magnetic domain A32 in the third region A3 changes, the domain wall DW moves. The domain wall DW is moved by passing a write current in the x direction of the third region A3, applying an external magnetic field to the third region A3, or the like. For example, when a write current (e.g., a current pulse) in the +x direction is applied to the third region A3, electrons flow in the −x direction opposite to the current, and the domain wall DW moves in the −x direction. When a current flows from the first magnetic domain A31 to the second magnetic domain A32, the spin-polarized electrons in the second magnetic domain A32 reverse the magnetization M_{A31} of the first magnetic domain A31. When the magnetization M_{A31} of the first magnetic domain A31 is reversed, the domain wall DW moves in the −x direction.

The domain wall displacement layer 10 is made of a magnetic material. The domain wall displacement layer 10 may be a ferromagnetic material, a ferrimagnetic material, or a combination of these with an antiferromagnetic material whose magnetic state can be changed by applying a current. The domain wall displacement layer 10 preferably includes at least one element selected from the group consisting of Co, Ni, Fe, Pt, Pd, Gd, Tb, Mn, Ge, and Ga. Examples of materials used for the domain wall displacement layer 10 include a laminated film of Co and Ni, a laminated film of Co and Pt, a laminated film of Co and Pd, an MnGa-based material, a GdCo-based material, and a TbCo-based material. Ferrimagnetic materials such as MnGa-based materials, GdCo-based materials, and TbCo-based materials have a small saturation magnetization, and the threshold current required to move the domain wall DW is small. Furthermore, the laminated film of Co and Ni, the laminated film of Co and Pt, and the laminated film of Co and Pd have a large coercive force, and the moving speed of the domain wall DW becomes slow. The antiferromagnetic material is, for example, Mn₃X (X is Sn, Ge, Ga, Pt, Ir, etc.), CuMnAs, Mn₂Au, etc. The domain wall displacement layer 10 may be made of the same material as the ferromagnetic layer 30 described later.

The non-magnetic layer 20 is located between the domain wall displacement layer 10 and the ferromagnetic layer 30. The non-magnetic layer 20 is laminated on one surface of the ferromagnetic layer 30.

The non-magnetic layer 20 is made of, for example, a non-magnetic insulator, a semiconductor, or a metal. The non-magnetic insulator is, for example, Al₂O₃, SiO₂, MgO, MgAl₂O₄, and materials in which part of the Al, Si, and Mg are replaced with Zn, Be, etc. These materials have a large band gap and excellent insulating properties. When the non-magnetic layer 20 is made of a non-magnetic insulator, the non-magnetic layer 20 is a tunnel barrier layer. Examples of non-magnetic metals include Cu, Au, Ag, etc. Examples of non-magnetic semiconductors include Si, Ge, CuInSe₂, CuGaSe₂, Cu(In, Ga)Se₂, etc.

The thickness of the non-magnetic layer 20 is, for example, 20 Å or more, and may be 25 Å or more. If the thickness of the non-magnetic layer 20 is large, the resistance area product (RA) of the magnetoresistance effect element 100 becomes large. The resistance area product (RA) of the magnetoresistance effect element 100 is preferably 1×10⁴ ΩμM² or more, and more preferably 5×10⁴ Ωμm² or more. The resistance area product (RA) of the magnetoresistance effect element 100 is expressed as the product of the element resistance of one magnetoresistance effect element 100 and the element cross-sectional area of the magnetoresistance effect element (the area of the cross section obtained by cutting the non-magnetic layer 20 in the xy plane).

The ferromagnetic layer 30 sandwiches the non-magnetic layer 20 together with the domain wall displacement layer 10. The ferromagnetic layer 30 is located so that at least a part of the ferromagnetic layer 30 overlaps with the domain wall displacement layer 10 in the z direction. The magnetization M₃₀ of the ferromagnetic layer 30 is more difficult to reverse than the magnetizations M_{A31} and M_{A32} of the third region A3 of the domain wall displacement layer 10. The magnetization M₃₀ of the ferromagnetic layer 30 does not change direction and is fixed when an external force is applied that is strong enough to reverse the magnetization of the third region A3. The ferromagnetic layer 30 may be referred to as a fixed layer or a reference layer.

The ferromagnetic layer 30 shown in FIG. 5 is closer to the substrate Sub than the domain wall displacement layer 10. A structure in which the ferromagnetic layer 30, which is a fixed layer, is closer to the substrate Sub than the domain wall displacement layer 10 is referred to as a bottom pin structure. In the bottom pin structure, the magnetization M₃₀ of the ferromagnetic layer 30 is highly stable.

The ferromagnetic layer 30 contains a ferromagnetic material. The ferromagnetic layer 30 contains a material that is likely to produce a coherent tunnel effect between the domain wall displacement layer 10 and the ferromagnetic layer 30. The ferromagnetic layer 30 contains, for example, a metal selected from the group consisting of Cr, Mn, Co, Fe, and Ni, an alloy containing one or more of these metals, and an alloy containing these metals and at least one of the elements B, C, and N. The ferromagnetic layer 30 is, for example, Co—Fe, Co—Fe—B, or Ni—Fe.

The ferromagnetic layer 30 may be, for example, a Heusler alloy. Heusler alloys are half-metallic and have high spin polarizability. Heusler alloys are intermetallic compounds with the chemical composition XYZ or X₂YZ, X is a transition metal element or a noble metal element of the Co, Fe, Ni, or Cu group on the periodic table, Y is a transition metal element or an element type of X of the Mn, V, Cr, or Ti group, and Z is a typical element of groups III to V. Examples of Heusler alloys include Co₂FeSi, Co₂FeGe, Co₂FeGa, Co₂MnSi, Co₂Mn₁₋ₐFeₐAl_{b}Si_{1-b}, and Co₂FeGe_{1-c}Ga_{c}.

The first conductive layer 40 is connected to an upper surface 10A of the domain wall displacement layer 10. The first conductive layer 40 is electrically connected to a first active region AA1 of the first transistor Tr1.

The first conductive layer 40 is, for example, a ferromagnetic material. For example, the same material as that of the domain wall displacement layer 10 and the ferromagnetic layer 30 can be used for the first conductive layer 40. The magnetization M₄₀ of the first conductive layer 40 fixes the magnetization M_{A1} of the first region A1.

Further, the first conductive layer 40 is not limited to a ferromagnetic material. The current density of the current flowing through the domain wall displacement layer 10 changes suddenly at the position from the third region A3 to the first region A1. Since the current density of the current flowing through the domain wall displacement layer 10 changes suddenly, the movement range of the domain wall DW can be limited, so that the first conductive layer 40 does not need to be made of a ferromagnetic material.

The second conductive layer 50 is connected to the upper surface 10A of the domain wall displacement layer 10. The first conductive layer 40 and the second conductive layer 50 are separated from each other in the x direction. The second conductive layer 50 is electrically connected to a fourth active region AA4 of the second transistor Tr2.

The second conductive layer 50 is, for example, a ferromagnetic material. The second conductive layer 50 may be made of, for example, the same material as the first conductive layer 40. The magnetization M₅₀ of the second conductive layer 50 fixes the magnetization M_{A2} of the second region A2. The film thickness of the second conductive layer 50 may be different from the film thickness of the first conductive layer 40. When the film thickness of the second conductive layer 50 is different from the film thickness of the first conductive layer 40, a difference occurs between the coercive force of the second conductive layer 50 and the coercive force of the first conductive layer 40, so that the magnetization orientation direction can be easily fixed in the opposite direction. The second conductive layer 50 is not limited to a ferromagnetic material.

The third conductive layer 60 is in contact with the ferromagnetic layer 30. The third conductive layer 60 electrically connects the ferromagnetic layer 30 and the third wiring RL. The third conductive layer 60 is a conductor.

The magnetoresistance effect element 100 may include layers other than the domain wall displacement layer 10, the non-magnetic layer 20, and the ferromagnetic layer 30. For example, a magnetic layer may be provided on the surface of the ferromagnetic layer 30 opposite to the non-magnetic layer 20 via a spacer layer. The ferromagnetic layer 30, the spacer layer, and the magnetic layer form a synthetic antiferromagnetic structure (SAF structure). The synthetic antiferromagnetic structure consists of two magnetic layers sandwiching a non-magnetic layer. The antiferromagnetic coupling between the ferromagnetic layer 30 and the magnetic layer increases the coercive force of the ferromagnetic layer 30 compared to a case where no magnetic layer is provided. The magnetic layer includes, for example, a ferromagnetic material and may include an antiferromagnetic material such as IrMn or PtMn. The spacer layer includes, for example, at least one selected from the group consisting of Ru, Ir, and Rh.

Further, for example, the magnetoresistance effect element 100 may also include an underlayer and a cap layer. The underlayer is a layer that is an underlying layer in the lamination direction and enhances the crystallinity of the ferromagnetic layer 30 and the domain wall displacement layer 10. The cap layer is an upper layer in the lamination direction, and enhances the crystallinity and magnetic anisotropy of the ferromagnetic layer 30 and the domain wall displacement layer 10.

The magnetization direction of each layer of the magnetoresistance effect element 100 can be confirmed by, for example, measuring a magnetization curve. The magnetization curve can be measured, for example, by using MOKE (Magneto Optical Kerr Effect). Measurement using MOKE is a measurement method of causing linearly polarized light to be incident on a measurement object and uses the magneto-optical effect (magnetic Kerr effect) in which the polarization direction rotates.

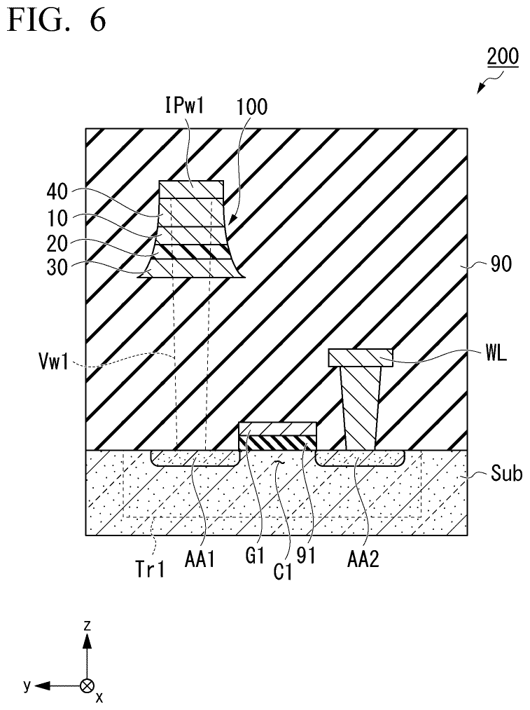

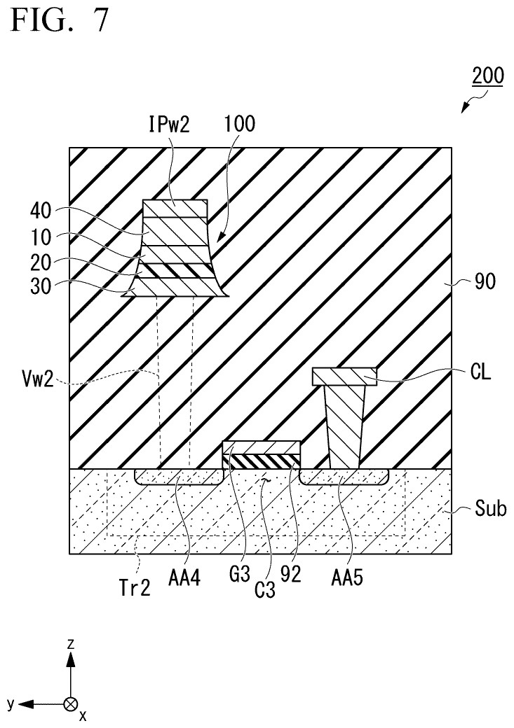

FIGS. 6 and 7 are cross-sectional views of the domain wall motion element 200 according to the first embodiment. FIG. 6 is a cross-sectional view taken along line B-B of FIG. 3. FIG. 7 is a cross-sectional view taken along line C-C of FIG. 3. In FIG. 6, the vertical wiring Vw1 on the front side of the paper is also shown by a dotted line. In FIG. 7, the vertical wiring Vw2 on the rear side of the paper is also shown by a dotted line.

The first transistor Tr1 and the second transistor Tr2 are formed on the substrate Sub. The substrate Sub is a semiconductor. The semiconductor is, for example, an oxide containing one or more elements selected from the group consisting of silicon, silicon carbide, gallium nitride, In, Ga, Zn, and Al (IGO, IZO, IGZO, IAZO, etc.). When an oxide containing one or more elements selected from the group consisting of In, Ga, Zn, and Al is applied to a transistor, the transistor can operate with low power consumption even when the gate width of the transistor is wide (when the rated current is large). This is because an oxide containing one or more elements selected from the group consisting of In, Ga, Zn, and Al has a small off-current.

The first transistor Tr1 includes the first active region AA1, a second active region AA2, a first gate G1, and agate insulating film 91. The second transistor Tr2 includes the fourth active region AA4, a fifth active region AA5, a third gate G3, and a gate insulating film 92.

The first active region AA1, the second active region AA2, the fourth active region AA4, and the fifth active region AA5 may be referred to as a source and a drain depending on the current flow direction. The first active region AA1, the second active region AA2, the fourth active region AA4, and the fifth active region AA5 are, for example, semiconductors doped with carriers.

The first active region AA1 is electrically connected to the domain wall displacement layer 10. The second active region AA2 is electrically connected to, for example, the first wiring WL. The fourth active region AA4 is electrically connected to the domain wall displacement layer 10. The fifth active region AA5 is electrically connected to, for example, the second wiring CL.

At least a part of the first active region AA1 is located at a position not overlapping with the domain wall displacement layer 10 when viewed from the z direction. This region is referred to as a non-overlapping region. The first active region AA1 is connected to the vertical wiring Vw1 in the non-overlapping region. The vertical wiring Vw1 and the first conductive layer 40 are electrically connected to the in-plane wiring IPw1. By providing the vertical wiring Vw1 in the non-overlapping region, this facilitates electrical connection between the upper surface 10A of the domain wall displacement layer 10 and the first active region AA1.

Similarly, at least a part of the fourth active region AA4 is located at a position not overlapping with the domain wall displacement layer 10 when viewed from the z direction. The fourth active region AA4 is connected to the vertical wiring Vw2 in the non-overlapping region. The vertical wiring Vw2 and the second conductive layer 50 are electrically connected to the in-plane wiring IPw2.

The first gate G1 controls the current between the first active region AA1 and the second active region AA2. The first gate G1 is, for example, a part of the first gate wiring extending in the x direction. The first gate G1 may be connected to, for example, the first gate wiring extending in the x direction. The first gate G1 applies a voltage to the first channel C1 via the gate insulating film 91 to control the current flowing through the first channel C1. The first channel C1 contains, for example, a semiconductor used for the substrate Sub. The gate insulating film 91 contains the same material as the insulating layer 90. The first gate G1 is a conductor.

The first gate G1 is located between the first active region AA1 and the second active region AA2 in the y direction when viewed from the z direction (see FIG. 3). The shortest distance between the first active region AA1 and the second active region AA2 is referred to as a first gate length L4, and the width of the first gate G1 in the direction orthogonal to the first gate length direction and the z direction is referred to as a first gate width L3. The direction that connects the shortest distance between the first active region AA1 and the second active region AA2 is referred to as the first gate length direction, and the direction orthogonal to the first gate length direction and the z direction is referred to as the first gate width direction.

The third gate G3 controls the current between the fourth active region AA4 and the fifth active region AA5. The third gate G3 is, for example, a part of the third gate wiring extending in the x direction. The third gate G3 may be connected to, for example, the third gate wiring extending in the x direction. The third gate G3 applies a voltage to a third channel C3 via the gate insulating film 92 to control the current flowing through the third channel C3. The third channel C3 contains, for example, a semiconductor used for the substrate Sub. The gate insulating film 92 contains the same material as the insulating layer 90. The third gate G3 is a conductor.

The third gate G3 is located between the fourth active region AA4 and the fifth active region AA5 in the y direction when viewed from the z direction. The shortest distance between the fourth active region AA4 and the fifth active region AA5 is referred to as a third gate length L6, and the width of the third gate G3 in the direction orthogonal to the third gate length direction and the z direction is referred to as a third gate width L5. The direction that connects the shortest distance between the fourth active region AA4 and the fifth active region AA5 is referred to as a third gate length direction, and the direction orthogonal to the third gate length direction and the z direction is referred to as a third gate width direction.

The length of the third gate G3 in the x direction is longer than the length thereof in the y direction. The x direction, for example, substantially coincides with the third gate width direction and intersects with (substantially perpendicular to) the third gate length direction. The length of the magnetoresistance effect element 100 in the x direction is longer than the length of the third gate G3 in the x direction. Further, the length L1 of the magnetoresistance effect element 100 in the x direction is shorter than the sum of the first gate width L3 and the third gate width L5.

When the sum of the first gate width L3 and the third gate width L5 is longer than the length L1 of the magnetoresistance effect element 100 in the x direction, a part of the first active region AA1 of the first transistor Tr1 and the fourth active region AA4 of the second transistor Tr2 protrudes from the magnetoresistance effect element 100 in the x direction when viewed from the z direction. That is, a non-overlapping region that does not overlap with the magnetoresistance effect element 100 when viewed from the z direction is formed in the first active region AA1 and the fourth active region AA4. When the non-overlapping region is used, this facilitates electrical connection between the upper surface 10A of the domain wall displacement layer 10 and the first active region AA1 or the fourth active region AA4. Further, it is possible to increase the rated current of the transistor while efficiently using the effective area by disposing the transistor at a position overlapping with the magnetoresistance effect element 100 in the substrate Sub when viewed from the z direction.

The domain wall motion element 200 according to this embodiment can be manufactured by a known method. The first transistor Tr1 and the second transistor Tr2 can be manufactured using, for example, photolithography. The first transistor Tr1 and the second transistor Tr2 may be a commercially available semiconductor substrate on which transistors are formed.

The magnetoresistance effect element 100 is formed by a lamination process of each layer and a processing process of processing a part of each layer into a predetermined shape. The layers can be laminated by sputtering, chemical vapor deposition (CVD), electron beam deposition (EB deposition), atomic laser deposition, etc. The layers can be processed by photolithography and etching (e.g., Ar etching), etc.

In the domain wall motion element 200 according to this embodiment, the longitudinal direction of the magnetoresistance effect element 100 and the longitudinal direction of the first transistor Tr1 are substantially aligned. Therefore, the domain wall motion element 200 can be compactly accommodated within a limited area. Further, since the longitudinal direction of the magnetoresistance effect element 100 and the longitudinal direction of the first transistor Tr1 are substantially aligned, the first gate width L3 of the first transistor Tr1 can be widened. The first transistor Tr1 having a wide first gate width L3 has a large rated current. A transistor with the large rated current can pass a sufficient amount of write current via the domain wall displacement layer 10. That is, the domain wall motion element 200 according to this embodiment can be highly integrated and can obtain the functions required for the domain wall motion element 200.

### Second Embodiment

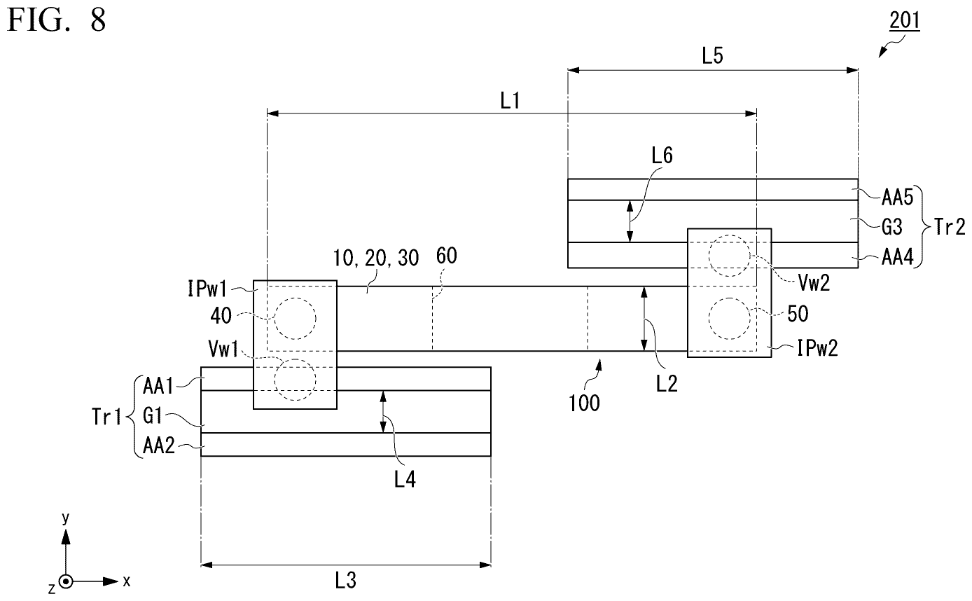

FIG. 8 is a plan view of a domain wall motion element 201 according to a second embodiment. The domain wall motion element 201 is different from the domain wall motion element 200 in the positional relationship of the first transistor Tr1 and the second transistor Tr2 with respect to the magnetoresistance effect element 100. The same components as those in the first embodiment are denoted by the same reference numerals, and the description thereof will be omitted.

The first transistor Tr1 and the second transistor Tr2 are located at positions not overlapping with the magnetoresistance effect element 100 when viewed from the z direction. FIG. 8 shows an example in which the first transistor Tr1 and the second transistor Tr2 are located in the opposite directions with respect to the magnetoresistance effect element 100, but the first transistor Tr1 and the second transistor Tr2 may be located in the same direction with respect to the magnetoresistance effect element 100.

When the first transistor Tr1 and the magnetoresistance effect element 100 are located at a non-overlapping position when viewed from the z direction, this facilitates electrical connection between the first conductive layer 40 connected to the upper surface 10A of the domain wall displacement layer 10 and the first active region AA1. Similarly, when the second transistor Tr2 and the magnetoresistance effect element 100 are located at a non-overlapping position when viewed from the z direction, this facilitates electrical connection between the second conductive layer 50 connected to the upper surface 10A of the domain wall displacement layer 10 and the fourth active region AA4.

The domain wall motion element 201 according to the second embodiment has the same effects as the domain wall motion element 200 according to the first embodiment. Further, the domain wall motion element 201 according to the second embodiment can be replaced with the domain wall motion element 200 of the integration region 1 shown in FIG. 2.

### Third Embodiment

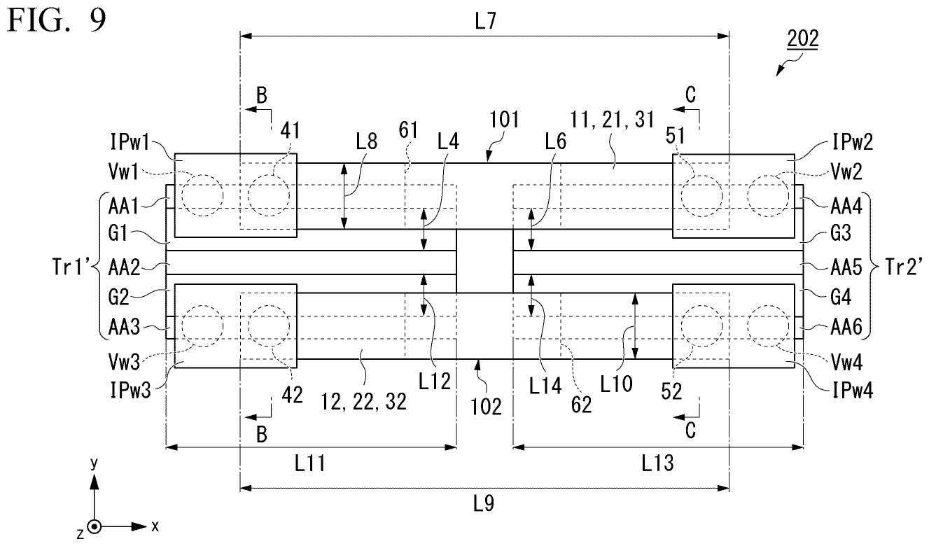

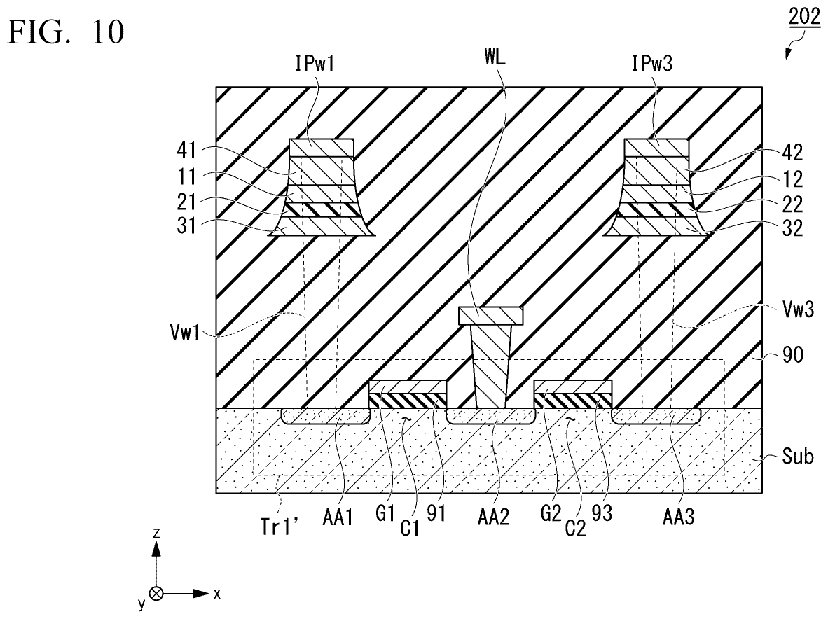

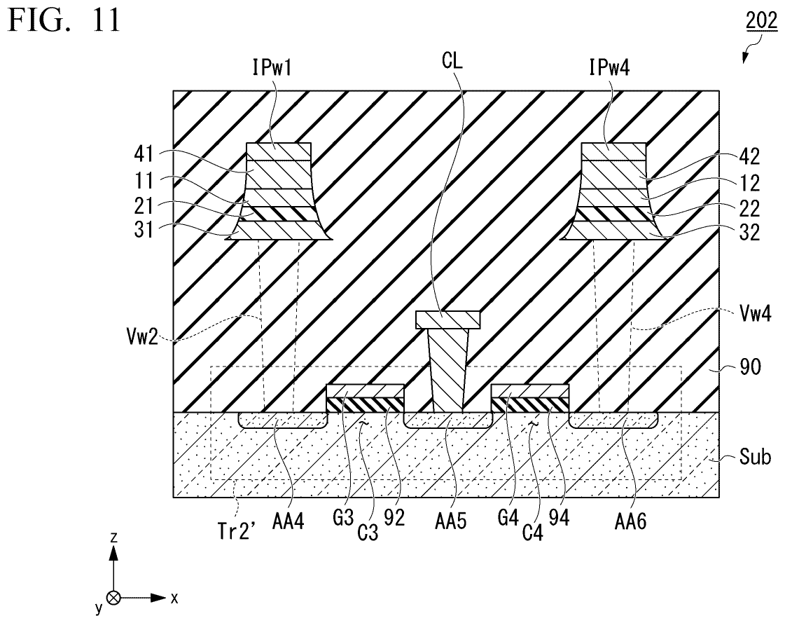

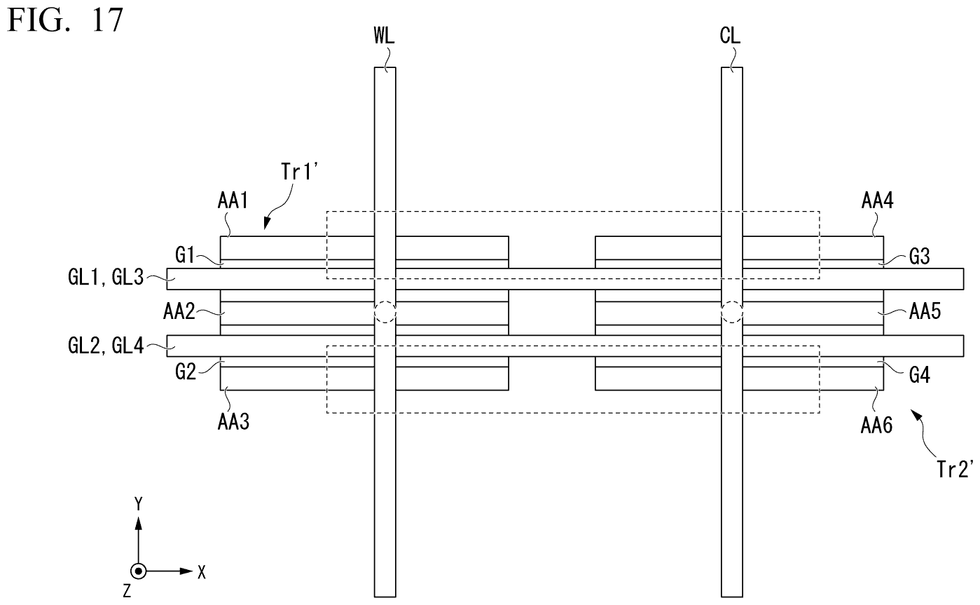

FIG. 9 is a plan view of a domain wall motion element 202 according to a third embodiment. FIGS. 10 and 11 are cross-sectional views of the domain wall motion element 202 according to the third embodiment. FIG. 10 is a cross-sectional view taken along line B-B of FIG. 9. FIG. 11 is a cross-sectional view taken along line C-C of FIG. 9. FIG. 17 is a plan view showing a wiring connected to the transistors (a first transistor Tr1′ and a second transistor Tr2′) of the domain wall motion element according to the third embodiment.

The domain wall motion element 202 includes a first magnetoresistance effect element 101, a second magnetoresistance effect element 102, the first transistor Tr1′, and the second transistor Tr2′.

The first magnetoresistance effect element 101 includes, for example, a domain wall displacement layer 11, a non-magnetic layer 21, a ferromagnetic layer 31, a first conductive layer 41, a second conductive layer 51, and a third conductive layer 61. The second magnetoresistance effect element 102 includes, for example, a domain wall displacement layer 12, a non-magnetic layer 22, a ferromagnetic layer 32, a first conductive layer 42, a second conductive layer 52, and a third conductive layer 62.

The domain wall displacement layers 11 and 12 correspond to the domain wall displacement layer 10. The non-magnetic layers 21 and 22 correspond to the non-magnetic layer 20. The ferromagnetic layers 31 and 32 correspond to the ferromagnetic layer 30. The first conductive layers 41 and 42 correspond to the first conductive layer 40. The second conductive layers 51 and 52 correspond to the second conductive layer 50. The third conductive layers 61 and 62 correspond to the third conductive layer 60. The detailed configuration of each layer is similar to the configuration of each layer according to the first embodiment.

When viewed from the z direction, a length L7 of the first magnetoresistance effect element 101 in the x direction is longer than a length L8 thereof in the y direction. When viewed from the z direction, a length L9 of the second magnetoresistance effect element 102 in the x direction is longer than a length L10 thereof in the y direction.

The first transistor Tr1′ includes the first active region AA1, the second active region AA2, a third active region AA3, the first gate G1, a second gate G2, the gate insulating film 91, and a gate insulating film 93. The first active region AA1, the second active region AA2, the first gate G1, and the gate insulating film 91 are the same as those in the first embodiment.

The third active region AA3 is located on the opposite side of the first active region AA1 with respect to the second active region AA2 when viewed from the z direction. The first active region AA1 and the third active region AA3 sandwich the second active region AA2 in the y direction when viewed from the z direction. The third active region AA3 contains the same material as that of the first active region AA1. The third active region AA3 is electrically connected to the domain wall displacement layer 12 via the vertical wiring Vw3, the in-plane wiring IPw3, and the first conductive layer 42. At least a part of the third active region AA3 is located at a position not overlapping with the domain wall displacement layer 12 when viewed from the z direction.

The second gate G2 controls the current between the second active region AA2 and the third active region AA3. The second gate G2 is, for example, a part of a second gate wiring GL2 extending in the x direction. The second gate G2 may be connected to, for example, the second gate wiring GL2 extending in the x direction. The second gate G2 applies a voltage to a second channel C2 via the gate insulating film 93 to control the current flowing through the second channel C2. The second channel C2 contains, for example, a semiconductor used for the substrate Sub. The gate insulating film 93 contains the same material as the gate insulating film 91. The second gate G2 is a conductor.

The second gate G2 is located between the second active region AA2 and the third active region AA3 in the y direction when viewed from the z direction. The shortest distance between the second active region AA2 and the third active region AA3 is referred to as a second gate length L12, and the width of the second gate G2 in the direction orthogonal to the second gate length direction and the z direction is referred to as a second gate width L11. The second gate width L11 is longer than the second gate length L12.

The second transistor Tr2′ includes the fourth active region AA4, the fifth active region AA5, a sixth active region AA6, the third gate G3, a fourth gate G4, the gate insulating film 92, and a gate insulating film 94. The fourth active region AA4, the fifth active region AA5, the third gate G3, and the gate insulating film 92 are the same as those in the first embodiment. In the third embodiment, a first gate wiring GL1 connected to the first gate G1 may be the same as a third gate wiring GL3 connected to the third gate G3. That is, the first gate G1 and the third gate G3 may be connected to the same gate wiring.

The sixth active region AA6 is located on the opposite side of the fourth active region AA4 with respect to the fifth active region AA5 when viewed from the z direction. The fourth active region AA4 and the sixth active region AA6 sandwich the fifth active region AA5 in the y direction when viewed from the z direction. The sixth active region AA6 contains the same material as that of the first active region AA1. The sixth active region AA6 is electrically connected to the domain wall displacement layer 12 via the vertical wiring Vw4, the in-plane wiring IPw4, and the second conductive layer 52. At least a part of the sixth active region AA6 is located at a position not overlapping with the domain wall displacement layer 12 when viewed from the z direction.

The fourth gate G4 controls the current between the fifth active region AA5 and the sixth active region AA6. The fourth gate G4 is, for example, a part of a fourth gate wiring GL4 extending in the x direction. The fourth gate G4 may be connected to, for example, the fourth gate wiring GL4 extending in the x direction. In the third embodiment, the second gate wiring GL2 connected to the second gate G2 may be the same as the fourth gate wiring GL4 connected to the fourth gate G4. That is, the second gate G2 and the fourth gate G4 may be connected to the same gate wiring. The fourth gate G4 applies a voltage to a fourth channel C4 via the gate insulating film 94 to control the current flowing through the fourth channel C4. The fourth channel C4 contains, for example, a semiconductor used for the substrate Sub. The gate insulating film 94 contains the same material as the gate insulating film 91. The fourth gate G4 is a conductor.

The fourth gate G4 is located between the fifth active region AA5 and the sixth active region AA6 in the y direction when viewed from the z direction. The shortest distance between the fifth active region AA5 and the sixth active region AA6 is referred to as a fourth gate length L14, and the width of the fourth gate G4 in the direction orthogonal to the fourth gate length direction and the z direction is referred to as a fourth gate width L13. The fourth gate width L13 is longer than the fourth gate length L14. Further, each of the lengths L7 and L9 of the first magnetoresistance effect element 101 and the second magnetoresistance effect element 102 in the x direction is shorter than the sum of the second gate width L11 and the fourth gate width L13.

The domain wall motion element 202 according to the third embodiment has the same effects as the domain wall motion element 200 according to the first embodiment. Further, the first magnetoresistance effect element 101 and the second magnetoresistance effect element 102 share the first wiring WL and the second wiring CL. Further, the first magnetoresistance effect element 101 and the second magnetoresistance effect element 102 share the second active region AA2 and the fifth active region AA5. That is, since the domain wall motion element 202 according to the third embodiment can decrease the number of transistors for operating the two magnetoresistance effect elements, higher integration can be obtained. Further, since the first gate G1 and the third gate G3 are connected to the same gate wiring, the number of gate wirings can be decreased. Similarly, since the second gate G2 and the fourth gate G4 are connected to the same gate wiring, the number of gate wirings can be decreased.

### Fourth Embodiment

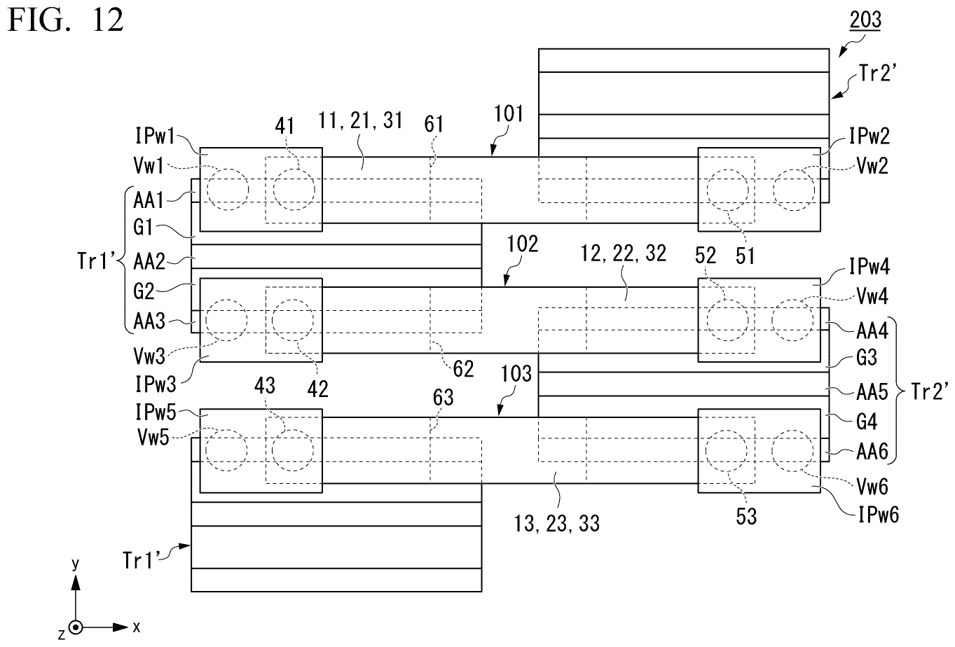

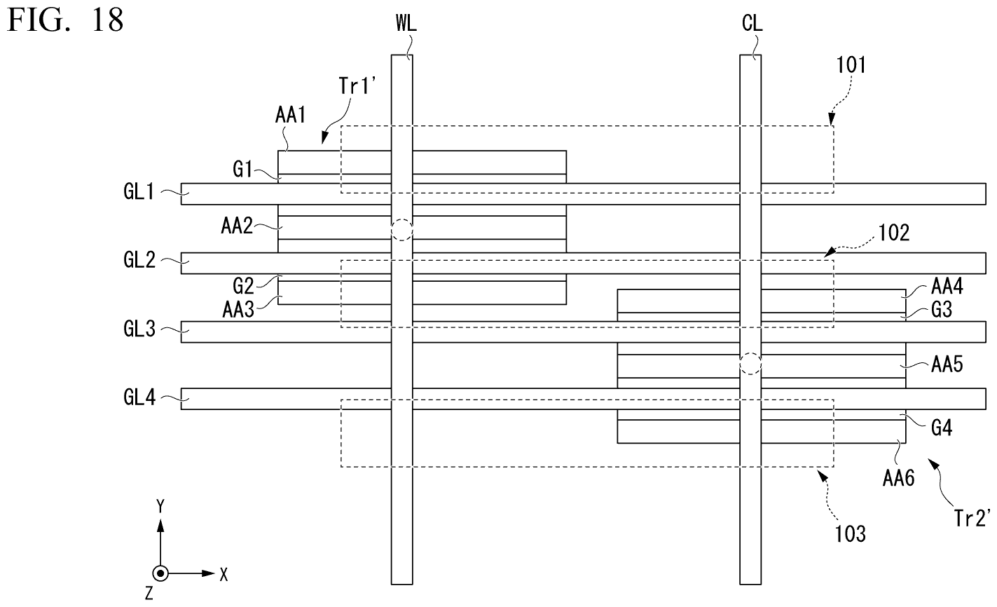

FIG. 12 is a plan view of a domain wall motion element 203 according to a fourth embodiment. The domain wall motion element 203 includes the first magnetoresistance effect element 101, the second magnetoresistance effect element 102, a third magnetoresistance effect element 103, the first transistor Tr1′, and the second transistor Tr2′. FIG. 18 is a plan view showing a wiring connected to the transistors (the first transistor Tr1′ and the second transistor Tr2′) of the domain wall motion element according to the fourth embodiment.

Each configuration of the first magnetoresistance effect element 101, the second magnetoresistance effect element 102, the first transistor Tr1′, and the second transistor Tr2′ is the same as that of the third embodiment. However, the fourth active region AA4 of the second transistor Tr2′ is connected to the domain wall displacement layer 12 of the second magnetoresistance effect element 102, and the sixth active region AA6 of the second transistor Tr2′ is connected to the domain wall displacement layer 13 of the third magnetoresistance effect element 103.

Further, as shown in FIG. 18, the first gate wiring GL1 connected to the first gate G1 of the first transistor Tr1′, the second gate wiring GL2 connected to the second gate G2 of the first transistor Tr1′, the third gate wiring GL3 connected to the third gate G3 of the second transistor Tr2′, and the fourth gate wiring GL4 connected to the fourth gate G4 of the second transistor Tr2′ are respectively located at different positions in the y direction. Since the second gate G2 and the third gate G3 are connected to different gate wirings (the second gate wiring GL2 and the third gate wiring GL3), the control of the first transistor Tr1′ by the second gate G2 and the control of the second transistor Tr2′ by the third gate G3 can be separately performed. For example, when the first transistor Tr1′ is turned off and the second transistor Tr2′ is turned on, the accuracy of reading data from the second magnetoresistance effect element 102 can be improved. Further, even when the magnetic array MA is used as a neuromorphic device or a multiply-accumulate calculator, the first transistor Tr1′ and the second transistor Tr2′ can be controlled separately to suppress leakage of the output current.

The third magnetoresistance effect element 103 includes, for example, a domain wall displacement layer 13, a non-magnetic layer 23, a ferromagnetic layer 33, a first conductive layer 43, a second conductive layer 53, and a third conductive layer 63. The domain wall displacement layer 13 corresponds to the domain wall displacement layer 10. The non-magnetic layer 23 corresponds to the non-magnetic layer 20. The ferromagnetic layer 33 corresponds to the ferromagnetic layer 30. The first conductive layer 43 corresponds to the first conductive layer 40. The second conductive layer 53 corresponds to the second conductive layer 50. The third conductive layer 63 corresponds to the third conductive layer 60. The detailed configuration of each layer is similar to the configuration of each layer according to the first embodiment.

The first magnetoresistance effect element 101 and the second magnetoresistance effect element 102 share the second active region AA2, and share the first wiring WL connected to the second active region AA2. Further, the second magnetoresistance effect element 102 and the third magnetoresistance effect element 103 share the fifth active region AA5, and share the second wiring CL connected to the fifth active region AA5.

The domain wall motion element 203 according to the fourth embodiment has the same effects as the domain wall motion element 200 according to the first embodiment. Further, in the domain wall motion element 203 according to the fourth embodiment, since a part of the transistor is shared by two magnetoresistance effect elements, the number of transistors can be decreased and higher integration can be obtained. Further, since the first transistor Tr1′ and the second transistor Tr2′ are arranged with a shift in the y direction, the first wiring WL connected to the second active region AA2 and the second wiring CL connected to the fifth active region AA5 are less likely to interfere with each other, which facilitates the layout of the wiring.

### Fifth Embodiment

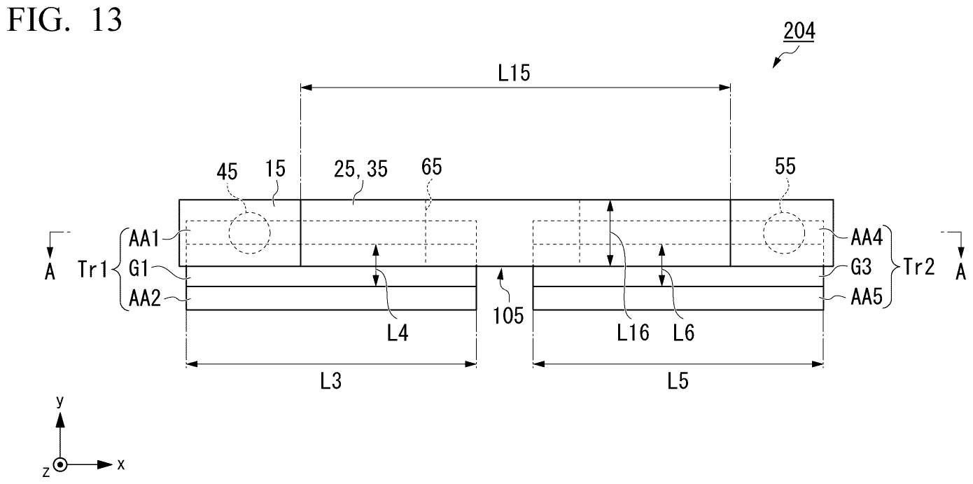

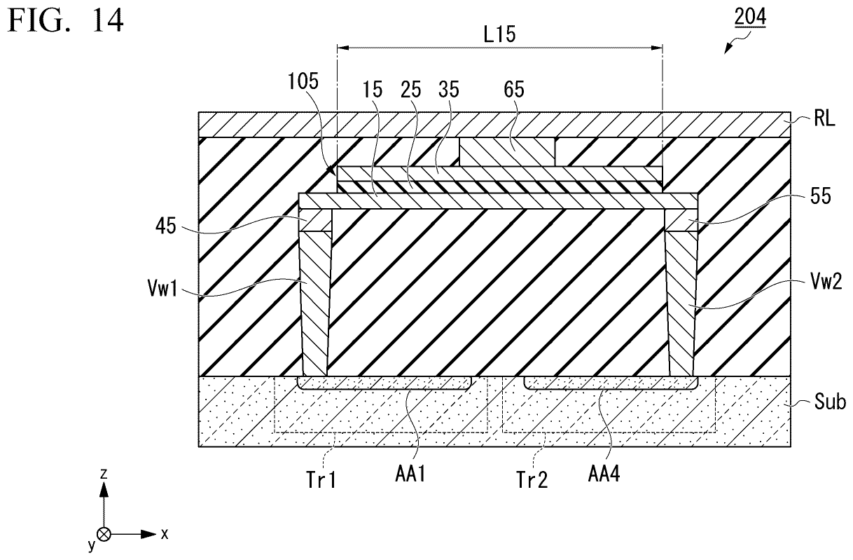

FIG. 13 is a plan view of a domain wall motion element 204 according to a fifth embodiment. FIG. 14 is a cross-sectional view of the domain wall motion element 204 according to the fifth embodiment. FIG. 14 is a cross-sectional view taken along line A-A of FIG. 13.

The domain wall motion element 204 includes a magnetoresistance effect element 105, the first transistor Tr1, and the second transistor Tr2. The detailed configurations of the first transistor Tr1 and the second transistor Tr2 are similar to those in the first embodiment.

The magnetoresistance effect element 105 includes the domain wall displacement layer 15, a non-magnetic layer 25, a ferromagnetic layer 35, a first conductive layer 45, a second conductive layer 55, and a third conductive layer 65. The domain wall displacement layer 15 corresponds to the domain wall displacement layer 10. The non-magnetic layer 25 corresponds to the non-magnetic layer 20. The ferromagnetic layer 35 corresponds to the ferromagnetic layer 30. The first conductive layer 45 corresponds to the first conductive layer 40. The second conductive layer 55 corresponds to the second conductive layer 50. The third conductive layer 65 corresponds to the third conductive layer 60.

The magnetoresistance effect element 105 is different from the magnetoresistance effect element 100 according to the first embodiment in the lamination order of each layer. The magnetoresistance effect element 105 is formed by laminating the domain wall displacement layer 15, the non-magnetic layer 25, and the ferromagnetic layer 35 in this order from the substrate Sub. The magnetoresistance effect element 105 is referred to as a top pin structure.

When viewed from the z direction, a length L15 of the magnetoresistance effect element 105 in the x direction is longer than a length L16 thereof in the y direction. In the case of the top pin structure, the length of the ferromagnetic layer 35 in the x direction may be different from the length of the domain wall displacement layer 15 in the x direction. As described above, the length L15 of the magnetoresistance effect element 105 in the x direction is the length of the portion where the domain wall displacement layer 15, the non-magnetic layer 25, and the ferromagnetic layer 35 overlap when viewed from the z direction.

The first conductive layer 45 electrically connected to the first active region AA1 is connected to the lower surface of the domain wall displacement layer 15. In the case of the top pin structure, since the domain wall displacement layer 15 is closer to the substrate Sub than the ferromagnetic layer 35, the magnetoresistance effect element 105 and the first transistor Tr1 may be connected only by the vertical wiring Vw1. Further, since the magnetoresistance effect element 105 can secure the electrical connection with the first transistor Tr1 at the lower surface of the domain wall displacement layer 15, the first active region AA1 may be covered with the domain wall displacement layer 15 when viewed from the z direction.

Similarly, the second conductive layer 55 electrically connected to the fourth active region AA4 is connected to the lower surface of the domain wall displacement layer 15. The magnetoresistance effect element 105 and the second transistor Tr2 may be connected only by the vertical wiring Vw2. Further, the fourth active region AA4 may be covered with the domain wall displacement layer 15 when viewed from the z direction.

The length L15 of the magnetoresistance effect element 105 in the x direction may be longer than the sum of the first gate width L3 of the first transistor Tr1 and the third gate width L5 of the second transistor Tr2. Since the magnetoresistance effect element 105 can secure the electrical connection with the first transistor Tr1 and the second transistor Tr2 at the lower surface of the domain wall displacement layer 15, the wiring connecting the magnetoresistance effect element 105 to the first transistor Tr1 or the second transistor Tr2 is less likely to become complicated even when the length L15 of the magnetoresistance effect element 105 in the x direction is longer than the sum of the first gate width L3 and the third gate width L5. Further, the transistor can be disposed in a portion of the substrate Sub that overlaps with the magnetoresistance effect element 105 when viewed from the z direction, and the effective area can be used efficiently.

The domain wall motion element 204 according to the fifth embodiment has the same effects as the domain wall motion element 200 according to the first embodiment. Further, the domain wall motion element 204 according to the fifth embodiment can simplify the wiring between the magnetoresistance effect element 105 and the first transistor Tr1 or the second transistor Tr2.

### Sixth Embodiment

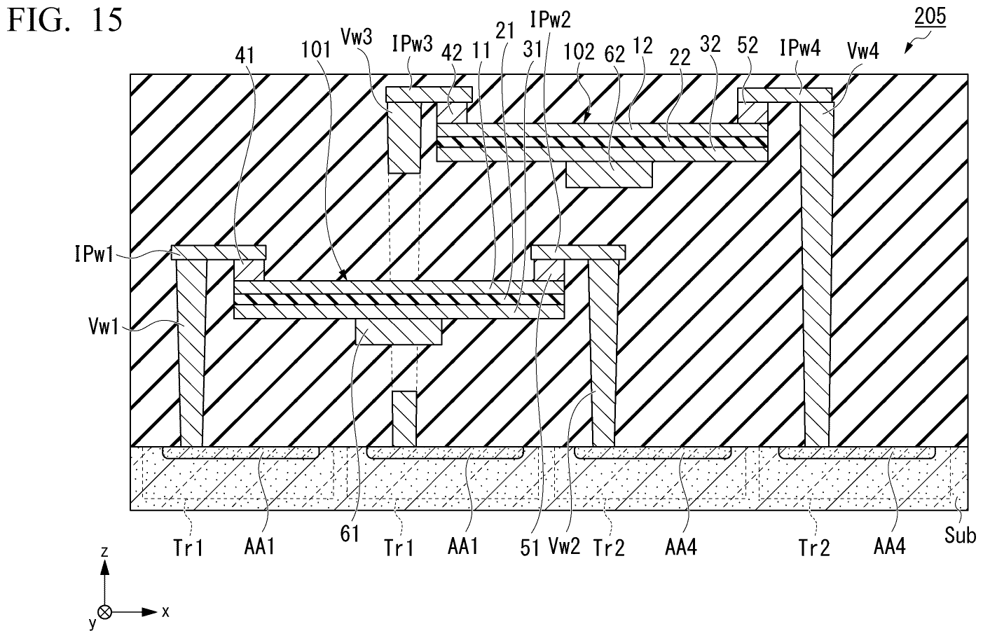

FIG. 15 is a cross-sectional view of a domain wall motion element 205 according to a sixth embodiment. FIG. 15 is a cross-sectional view of an xz plane passing through the center of the domain wall displacement layer 11 in the y direction.

The domain wall motion element 205 according to the sixth embodiment includes the first magnetoresistance effect element 101, the second magnetoresistance effect element 102, the first transistor Tr1, and the second transistor Tr2. In FIG. 15, the same components as those in the above-described embodiments are denoted by the same reference numerals, and the description thereof will be omitted.

The first magnetoresistance effect element 101 and the second magnetoresistance effect element 102 are located at different positions in the z direction. For example, the first magnetoresistance effect element 101 and the second magnetoresistance effect element 102 partially overlap with each other when viewed from the z direction.

The domain wall motion element 205 according to the sixth embodiment has the same effects as the domain wall motion element 200 according to the first embodiment. Further, since the domain wall motion element 205 can be arranged three-dimensionally, integration is more excellent.

### Seventh Embodiment

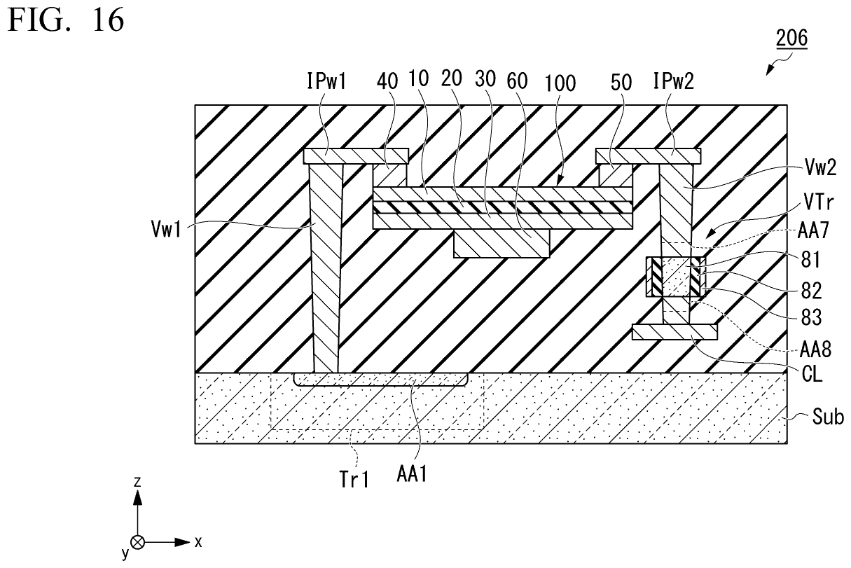

FIG. 16 is a cross-sectional view of a domain wall motion element 206 according to a seventh embodiment. FIG. 16 is a cross-sectional view of an xz plane passing through the center of the domain wall displacement layer 10 in the y direction.

The domain wall motion element 206 according to the seventh embodiment includes the magnetoresistance effect element 100, the first transistor Tr1, and a vertical transistor VTr. In FIG. 16, the same components as those in the above-described embodiments are denoted by the same reference numerals, and the description thereof will be omitted.

In the domain wall motion element 206, the second transistor Tr2 of the domain wall motion element 200 is replaced with the vertical transistor VTr. The vertical transistor VTr includes, for example, a core 81, a gate insulating film 82, and a gate 83.

The core 81 is a semiconductor. The gate insulating film 82 covers the periphery of the core 81. The gate insulating film 82 contains the same material as the gate insulating film 91. The gate 83 covers the periphery of the gate insulating film 82. The gate 83 applies a voltage to the core 81 via the gate insulating film 82 to control the current flowing through the core 81. When a voltage is applied to the gate 83, a channel which connects two active regions AA7 and AA8 is formed inside the core 81 in the z direction.

The domain wall motion element 206 according to the seventh embodiment has the same effects as the domain wall motion element 200 according to the first embodiment. Further, since the domain wall motion element 206 has a transistor arranged vertically, integration is more excellent. Further, the vertical transistor VTr only needs to be applied to any one of the plurality of domain wall motion elements, and does not need to be applied to all of the domain wall motion elements.

Although the preferred embodiments of the present disclosure have been described above in detail, the present disclosure is not limited to these embodiments. For example, characteristic configurations of the respective embodiments may be combined, or a part thereof may be modified without departing from the spirit of the invention.

### REFERENCE SIGNS LIST

1 Integration region
2 Peripheral region
3 Pulse application device
4 Resistance detection device
5 Output unit
6 Control unit
7 Power source
10, 11, 12, 13, 15 Domain wall displacement layer
10A Upper surface
20, 21, 22, 23, 25 Non-magnetic layer
30, 31, 32, 33, 35 Ferromagnetic layer
40, 41, 42, 43, 45 First conductive layer
50, 51, 52, 53, 55 Second conductive layer
60, 61, 62, 63, 65 Third conductive layer
81 Core
82, 91, 92, 93, 94 Gate insulating film
83 Gate
90 Insulating layer
100, 105 Magnetoresistance effect element
101 First magnetoresistance effect element
102 Second magnetoresistance effect element
103 Third magnetoresistance effect element
200, 201, 202, 203, 204, 205, 206 Domain wall motion element
AA1 First active region
AA2 Second active region
AA3 Third active region
AA4 Fourth active region
AA5 Fifth active region
AA6 Sixth active region
AA7, AA8 Active region
C1 First channel
C2 Second channel
C3 Third channel
C4 Fourth channel
G1 First gate
G2 Second gate
G3 Third gate
G4 Fourth gate
Tr1, Tr1′ First transistor
Tr2, Tr2′ Second transistor
VTr Vertical transistor

1. A domain wall motion element, comprising:
a first magnetoresistance effect element; and
a first transistor,
wherein the first magnetoresistance effect element includes a first domain wall displacement layer, a first ferromagnetic layer, and a first non-magnetic layer sandwiched between the first domain wall displacement layer and the first ferromagnetic layer,
wherein the first transistor includes a first active region, a second active region, and a first gate controlling a current between the first active region and the second active region,
wherein the first domain wall displacement layer is electrically connected to the first active region,
wherein a length of the first magnetoresistance effect element in a first direction is longer than a length thereof in a second direction orthogonal to the first direction,
wherein a length of the first gate in the first direction is longer than a length thereof in the second direction,
wherein a length of the first magnetoresistance effect element in the first direction is longer than a length of the first gate in the first direction, and
wherein a first gate length direction of connecting the first active region and the second active region intersects with the first direction.

2. The domain wall motion element according to claim 1, further comprising:
a second magnetoresistance effect element,
wherein the second magnetoresistance effect element includes a second domain wall displacement layer, a second ferromagnetic layer, and a second non-magnetic layer sandwiched between the second domain wall displacement layer and the second ferromagnetic layer,
wherein the first transistor further includes a third active region and a second gate controlling a current between the second active region and the third active region, and
wherein the second domain wall displacement layer is electrically connected to the third active region.

3. The domain wall motion element according to claim 2, further comprising:
a second transistor,
wherein the second transistor includes a fourth active region, a fifth active region, a sixth active region, a third gate controlling a current between the fourth active region and the fifth active region, and a fourth gate controlling a current between the fifth active region and the sixth active region,
wherein the fourth active region is electrically connected to the first domain wall displacement layer, and
wherein the sixth active region is electrically connected to the second domain wall displacement layer.

4. The domain wall motion element according to claim 2, further comprising:
a second transistor; and
a third magnetoresistance effect element,
wherein the second transistor includes a fourth active region, a fifth active region, a sixth active region, a third gate controlling a current between the fourth active region and the fifth active region, and a fourth gate controlling a current between the fifth active region and the sixth active region,
wherein the third magnetoresistance effect element includes a third domain wall displacement layer, a third ferromagnetic layer, and a third non-magnetic layer sandwiched between the third domain wall displacement layer and the third ferromagnetic layer,
wherein the fourth active region is electrically connected to the second domain wall displacement layer, and
wherein the sixth active region is electrically connected to the third domain wall displacement layer.

5. The domain wall motion element according to claim 1, further comprising:
a substrate,
wherein the first ferromagnetic layer is closer to the substrate than the first domain wall displacement layer, and
wherein a first conductive layer electrically connected to the first active region is connected to an upper surface of the first domain wall displacement layer.

6. The domain wall motion element according to claim 5,
wherein at least a part of the first active region does not overlap with the first domain wall displacement layer when viewed from a lamination direction.

7. The domain wall motion element according to claim 1, further comprising:
a second transistor,
wherein the second transistor includes a fourth active region, a fifth active region, and a third gate controlling a current between the fourth active region and the fifth active region,
wherein a length of the third gate in the first direction is longer than a length thereof in the second direction, and
wherein a length of the first magnetoresistance effect element in the first direction is shorter than a sum of the lengths of the first gate and the third gate in the first direction.

8. The domain wall motion element according to claim 1,
wherein a first channel between the first active region and the second active region contains an oxide containing any one or more elements selected from the group consisting of In, Ga, Zn, and Al.

9. The domain wall motion element according to claim 1, further comprising:
a second magnetoresistance effect element,
wherein the second magnetoresistance effect element includes a second domain wall displacement layer, a second ferromagnetic layer, and a second non-magnetic layer sandwiched between the second domain wall displacement layer and the second ferromagnetic layer, and
wherein the first magnetoresistance effect element and the second magnetoresistance effect element are respectively located at different positions in a lamination direction.

10. The domain wall motion element according to claim 1, further comprising:
a second magnetoresistance effect element,
wherein the second magnetoresistance effect element includes a second domain wall displacement layer, a second ferromagnetic layer, and a second non-magnetic layer sandwiched between the second domain wall displacement layer and the second ferromagnetic layer, and
wherein at least one transistor connected to the first magnetoresistance effect element or the second magnetoresistance effect element has a channel formed in a lamination direction connecting two active regions.

11. A magnetic array comprising:
the domain wall motion element according to claim 1.

12. The domain wall motion element according to claim 4, further comprising:
a second gate wiring connected to the second gate; and
a third gate wiring connected to the third gate,
wherein the second gate wiring and the third gate wiring are located at different positions in a second direction.

13. The domain wall motion element according to claim 1, further comprising:
a second transistor,
wherein the second transistor includes a fourth active region, a fifth active region, a sixth active region, a third gate controlling a current between the fourth active region and the fifth active region, and a fourth gate controlling a current between the fifth active region and the sixth active region,
wherein the first transistor further includes a third active region and a second gate controlling a current between the second active region and the third active region, and
wherein a first gate wiring connected to the first gate, a second gate wiring connected to the second gate, a third gate wiring connected to the third gate, and a fourth gate wiring connected to the fourth gate are respectively located at different positions in the second direction.
